(19) United States
(12) Patent Application Publication
(10) Pub. No.: US 2012/0006398 A1
(43) Pub. Date: Jan. 12, 2012

(54) PROTECTIVE BACK CONTACT LAYER FOR SOLAR CELLS

(75) Inventors: Nguyet Nguyen, Oro Valley, AZ (US); Urs Schoop, Tucson, AZ (US); Walter Stross, Tucson, AZ (US); Cay-Uwe Pinnow, Berlin (DE); Steffen Schuler, Berlin (DE); Toias Enzenhofer, Berlin (DE)

(73) Assignee: GLOBAL SOLAR ENERGY, INC., Tucson, AZ (US)

(21) Appl. No.: 12/976,976

(22) Filed: Dec. 22, 2010

Related U.S. Application Data
(60) Provisional application No. 61/284,923, filed on Dec. 28, 2009.
(60) Provisional application No. 61/351,245, filed on Jun. 3, 2010.
(60) Provisional application No. 61/425,641, filed on Dec. 21, 2010.

(51) Int. Cl. H01L 31/0216; H01L 31/18; H01L 31/0203

(52) U.S. Cl. 136/256; 438/64; 257/E31.117

(57) ABSTRACT

The present disclosure is directed toward a thin film photovoltaic cell including a support substrate; a contact layer disposed adjacent a first side of the substrate; a p-type semiconductor layer disposed on the first side of the substrate; an n-type semiconductor layer disposed on the first side of the substrate; and a protective back side layer structure disposed adjacent a second side of the substrate, wherein the protective back side layer structure may include a corrosion resistant material. In some embodiments, the back side layer includes at least a first layer and a second layer. Additionally and/or alternatively, the back side layer may include a molybdenum alloy, wherein the molybdenum alloy may include an alloy partner selected from the group consisting of Ti, Zr, Hf, V, Nb, Ta, Al, and Si.

### CROSS-REFERENCES TO RELATED APPLICATIONS

This application claims priority to U.S. Provisional Patent Application Ser. No. 61/284,923 filed Dec. 28, 2009, Ser. No. 61/351,245 filed Jun. 3, 2010, and Ser. No. 61/425,641 filed Dec. 21, 2010, all of which are incorporated herein by reference in their entirety for all purposes. Also incorporated by reference in their entireties are the following patents and patent applications: U.S. Pat. No. 7,194,197, Ser. No. 12/424,497 filed Apr. 15, 2009 and Ser. No. 12/397,846 filed Mar. 4, 2009.

### BACKGROUND

The field of photovoltaics generally relates to multi-layer materials that convert sunlight directly into DC electrical power. The basic mechanism for this conversion is the photovoltaic effect, first observed by Antoine-César Becquerel in 1839, and first correctly described by Einstein in a seminal 1905 scientific paper for which he was awarded a Nobel Prize for physics. In the United States, photovoltaic (PV) devices are popularly known as solar cells or PV cells. Solar cells are typically configured as a cooperating sandwich of p-type and n-type semiconductors, in which the n-type semiconductor material (on one “side” of the sandwich) exhibits an excess of electrons, and the p-type semiconductor material (on the other “side” of the sandwich) exhibits an excess of holes, each of which signifies the absence of an electron. Near the p-n junction between the two materials, valence electrons from the n-type layer move into neighboring holes in the p-type layer, creating a small electrical imbalance inside the solar cell. This results in an electric field in the vicinity of the metallurgical junction that forms the electronic p-n junction.

When an incident photon excites an electron in the cell into the conduction band, the excited electron becomes unbound from the atoms of the semiconductor, creating a free electron/hole pair. Because, as described above, the p-n junction creates an electric field in the vicinity of the junction, electron/hole pairs created in this manner near the junction tend to separate and move away from junction, with the electron moving toward the electrode on the n-type side, and the hole moving toward the electrode on the p-type side of the junction. This creates an overall charge imbalance in the cell, so that if an external conductive path is provided between the two sides of the cell, electrons will move from the n-type side back to the p-type side along the external path, creating an electric current. In practice, electrons may be collected from at or near the surface of the n-type side by a conducting grid that covers a portion of the surface, while still allowing sufficient access into the cell by incident photons.

Such a photovoltaic structure, when appropriately located electrical contacts are included and the cell (or a series of cells) is incorporated into a closed electrical circuit, forms a working PV device. As a standalone device, a single conventional solar cell is not sufficient to power most applications. As a result, solar cells are commonly arranged into PV modules, or “strings,” by connecting the front of one cell to the back of another, thereby adding the voltages of the individual cells together in electrical series. Typically, a significant number of cells are connected in series to achieve a usable voltage. The resulting DC current then may be fed through an inverter, where it is transformed into AC current at an appropriate frequency, which is chosen to match the frequency of AC current supplied by a conventional power grid. In the United States, this frequency is 60 Hertz (Hz), and most other countries provide AC power at either 50 Hz or 60 Hz.

One particular type of solar cell that has been developed for commercial use is a “thin-film” PV cell. In comparison to other types of PV cells, such as crystalline silicon PV cells, thin-film PV cells require less light-absorbing semiconductor material to create a working cell, and thus can reduce processing costs. Thin-film based PV cells also offer reduced cost by employing previously developed deposition techniques for the electrode layers, where similar materials are widely used in the thin-film industries for protective, decorative, and functional coatings. Common examples of low cost commercial thin-film products include water impermeable coatings on polymer-based food packaging, decorative coatings on architectural glass, low emissivity thermal control coatings on residential and commercial glass, and scratch and anti-reflective coatings on eyewear. Adopting or modifying techniques that have been developed in these other fields has allowed a reduction in development costs for PV cell thin-film deposition techniques.

Furthermore, thin-film cells have exhibited efficiencies approaching 20%, which rivals or exceeds the efficiencies of the most efficient crystalline cells. In particular, the semiconductor material copper indium gallium diselenide (CIGS) is stable, has low toxicity, and is truly a thin film, requiring a thickness of less than two microns in a working PV cell. As a result, to date CIGS appears to have demonstrated the greatest potential for high performance, low cost thin-film PV products, and thus for penetrating bulk power generation markets. Other semiconductor variants for thin-film PV technology include copper indium diselenide, copper indium disulfide, copper indium aluminum diselenide, and cadmium telluride.

Thin-film PV cells using either rigid or flexible substrates generally include a conductive layer, which serves as the lower electrode of the cell, disposed between the underlying substrate and the active PV material. When cells are interconnected by monolithic integration techniques (i.e., when the electrical connections between the cells are created in situ on the continuous substrate), the so-called P2 patterning step is used to divide the continuously formed PV material into cells for subsequent interconnection.

### SUMMARY

A thin film photovoltaic cell includes a support substrate; a contact layer disposed adjacent a first side of the substrate; a p-type semiconductor layer disposed on the first side of the substrate; an n-type semiconductor layer disposed on the first side of the substrate; and a protective back side layer structure disposed adjacent a second side of the substrate, wherein the protective back side layer structure may include a corrosion resistant material. In some embodiments, the back side layer includes at least a first layer and a second layer. Additionally and/or alternatively, the back side layer may include a molybdenum alloy, wherein the molybdenum alloy may include an alloy partner selected from the group consisting of Ti, Zr, Hf, V, Nb, Ta, Al, and Si.

A method of producing a flexible, thin-film photovoltaic (PV) structure includes steps of providing a support substrate; applying a layer of a photovoltaic layer structure on a first side of the substrate; and applying a protective back side layer structure on a second side of the substrate, wherein the protective back side layer structure includes a corrosion resistant material. In some embodiments, applying the protective back side layer structure includes applying at least two layers, and/or applying a protective back side layer structure includes applying a first layer and a second layer having a thickness ratio of 1:2, wherein the first layer includes chromium and the second layer includes molybdeunum. Additionally and/or alternatively, applying the protective back side layer structure includes applying a molybdenum-alloy layer, wherein the molybdenum alloy includes an alloy partner selected from the group consisting of Ti, Zr, Hf, V, Nb, Ta, Al, and Si.

An additional aspect of the present disclosure is directed towards a method of producing an elongate, flexible, photovoltaic (PV)-material strip comprising providing an elongate, flexible-strip support substrate, placing that substrate, in time succession, into different, self-isolated processing chambers; and within each chamber, performing different, time-successive sublayer-creation operations which collectively result in the making of an elongate, roll-contained, flexible, PV-material strip. The PV-material strip may include, on a first side, plural-layer, thin-film PV-cell layer structure and, on a second side, a protective back side layer structure, wherein the protective back side layer structure includes a corrosion resistant material. The protective back side layer structure may include a first layer including chromium and a second layer including molybdenum. Additionally and/or alternatively, the protective back side layer structure may include a molybdenum alloy layer, wherein the molybdenum alloy includes an alloy partner selected from the group consisting of Ti, Zr, Hf, V, Nb, Ta, Al, and Si.

The advantages of the present disclosure will be understood more readily after a consideration of the drawings and the Detailed Description.

### BRIEF DESCRIPTION OF THE DRAWINGS

FIG. 1 is a simplified schematic view generally illustrating process steps and stages employed for creating a PV module.

FIG. 2 is a fragmentary, simplified cross section of a PV cell including a protective back side layer structure.

FIG. 3 is a fragmentary, simplified cross section of a PV cell including a protective back side layer structure.

FIG. 4 is a cross sectional view of a portion of a monolithically integrated thin film photovoltaic module.

FIG. 5 is a graph comparing the electrical resistance of a thin film of molybdenum and a thin film of molybdenum-tantalum as a function of hours of exposure to damp heat.

### DETAILED DESCRIPTION

PV cells may be susceptible to damaging environmental conditions, for example during the application of a PV absorber layer by vacuum evaporation, during damp heat integrity testing, or due to environmental heat, humidity and/or moisture reaching a supporting substrate from the back side after installation of the PV cell or module. Molybdenum (Mo) coatings or layers disposed on either side of a supporting substrate may be susceptible to corrosion after periods of exposure to heat and moisture. A thin-film PV cell in accordance with the present disclosure includes an improved corrosion resistance over a substrate having a Mo layer alone.

Additionally and/or alternatively, a thin-film PV cell in accordance with the present disclosure may include a support substrate having photovoltaic layer structure disposed on a first side of the substrate and a protective back side layer structure disposed adjacent a second side of the substrate, wherein the protective back side layer structure improves the corrosion resistance of the substrate and/or protects the substrate from damaging environmental conditions. In accordance with one embodiment of the present disclosure, a protective back side layer structure may include a corrosion resistant material, such as a Mo—X alloy. Additionally and/or alternatively, in accordance with the present disclosure, a PV cell may include a protective back side layer structure having more than one layer, also referred to as a bi-layer, wherein one or more of the layers includes a corrosion resistant material, for example Chromium (Cr).

A PV cell in accordance with the present disclosure may be created by starting with a substrate, and then sequentially depositing multiple thin layers of different materials onto the substrate. When the substrate is flexible, this assembly may be accomplished through a roll-to-roll process whereby the substrate travels from a pay-out roll to a take-up roll, traveling through a series of deposition regions between the two rolls. Regardless of whether the PV material is manufactured in a roll-to-roll process or by some other technique, the material then may be cut to cells of any desired size and subsequently interconnected. Alternatively, various layers of the deposited material may be etched or otherwise divided during manufacture. Further details relating to the composition and manufacture of thin-film PV cells of a type suitable for use with the presently disclosed methods and apparatus may be found, for example, in U.S. Pat. No. 7,194,197 to Wendt et al., Ser. No. 12/424,497 filed Apr. 15, 2009 and Ser. No. 12/397,846 filed Mar. 4, 2009. These references are hereby incorporated into the present disclosure by reference for all purposes.

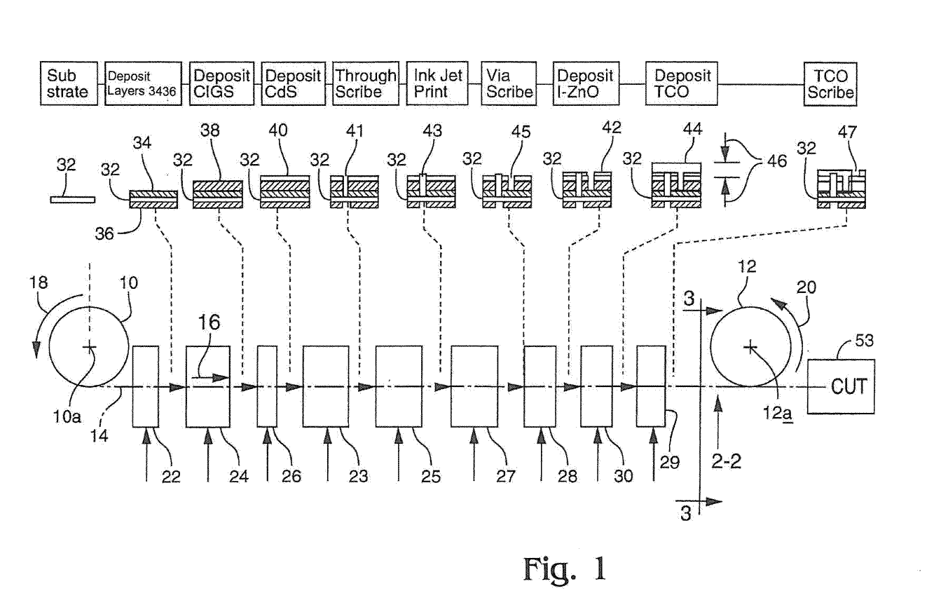

FIG. 1 illustrates an exemplary process for making a PV cell or module including a protective back layer structure in a roll-to-roll, continuous-motion in accordance with the present invention. Those skilled in the art should understand that, while roll-to-roll, continuous motion processing is employed in the described embodiment, non-roll-to-roll procedures could also be used effectively.

FIG. 1 shows two rolls 10, 12, at the left and right, respectively, which symbolize the several roll-to-roll, continuous-motion processing stages employed in the manufacturing of this new kind of PV module. Roll 10 represents a pay-out roll, and roll 12, a take-up roll. It should be understood that rolls 10, 12 are representative of the different pay-out and take-up rolls that are employed in different isolated processing chambers. Thus, there are typically multiple pay-out and take-up rolls used during the overall process.

A stretched-out, flat portion of an elongate strip of thin, flexible, substrate material 14 is shown extending between rolls 10, 12. This substrate strip has different amounts of applied (deposited) PV-cell layer structure at different positions between the rolls. The strip has opposite end winds that are distributed as turns on pay-out roll 10 and take-up roll 12. The direction of travel of the strip material during processing is indicated generally by arrow 16. Curved arrows 18, 20 indicate, symbolically, the related, associated directions of rotation of rolls 10, 12 about axes 10a, 12a, respectively, which are generally normal to the plane of FIG. 1.

Reference herein to the substrate strip material 14 should be understood to be reference to a strip of material whose overall structural character changes as the material travels, in accordance with processing steps, between rolls 10 and 12. Through the processing steps, layers of various components that go into the fabrication of the type of PV-module are added.

Nine separate individual processing chambers 22, 24, 26 23, 25, 27, 28, 30, 29 are illustrated as rectangular blocks in FIG. 1. The various layers of materials that are used to form a PV module according to this invention are applied or modified in these chambers. The relative sizes of these blocks as pictured in FIG. 1 are not important. It should be noted that the steps represented by some of the processing chambers are optional in some applications. For instance, a i-ZnO layer created in chamber 28 may be omitted and/or additional steps may be included in some applications.

Processing begins with a bare starter roll, or strip, of elongate thin-film, flexible substrate material supplied from pay-out roll 10. The uncoated material may have a width of about 33-cm, a thickness of about 0.005-cm, and a length of up to about 300-meters. The width, thickness and length dimensions are, of course, matters of choice, depending on the ultimate intended application for finished PV modules. The substrate material may include PI, any high-temperature polymer, or a thin metal such as stainless steel, titanium, covar, invar, tantalum, brass and niobium etc

A stress-compliant metal interlayer, for example Ni—V, chosen to have intermediate thermal expansion characteristics between the substrate and subsequently-applied layers can be optionally utilized as the first layer deposited onto the substrate. This step is not illustrated in FIG. 1, but can either be accomplished in a chamber similar in construction to chamber 22 or within a separate processing zone in chamber 22.

Within chamber 22, two or more layers may be formed on the opposite sides, or faces, of substrate 32. These two layers are shown on the opposite faces (top and bottom in FIG. 1) of fragment 32 at 34, 36 above chamber 22. Layer 34 forms a back contact layer for the PV module of the present disclosure. Layer 34 may include Mo or, in the case of a stainless steel substrate strip, the Mo back contact layer may be replaced with a Cr/Mo bilayer.

Layer 36 forms a protective back side layer structure in accordance with the present disclosure. Protective back side layer structure 36 may include a corrosion resistant material, such as a Mo—X alloy. Additionally and/or alternatively, in accordance with the present disclosure, protective back side layer structure 36 may include more than one layer, also referred to as a bi-layer, wherein one or more of the layers includes a corrosion resistant material. For example, protective back side layer structure 36 may include a Cr/Mo bilayer.

Back contact layer 34 and protective back side layer structure 36 may be applied via sputter deposition and/or may be applied, in the same chamber 22 within separate processing zones and/or may be applied in separate chambers. Notable characteristics of layers 34, 36 include: (a) that each of these layers bonds strongly to its associated substrate strip face; and (b) that these layers are able to tolerate temperature changes that occur in subsequent processing without suffering temperature-induced cracking and fracturing. Additionally, layers 34, 36, disposed as they are on the opposite faces of the substrate strip material, mechanically “balance” one another to inhibit product curling, or “bending out of plane.” Such bending could be a problem and/or an inconvenience if only a single layer on one side were used. By way of example, the induced internal compression in a single Mo layer would be sufficient to curl the substrate to the diameter of a pencil without the balancing effect of the opposite layer.

Material emerging from chamber 22 is ready for introduction into chamber 24, wherein an absorber layer 38, such as a p-type semiconductor in the form of copper-indium-gallium-diselenide (CIGS), or its readily acceptable counterpart, copper-indium-diselenide (CIS), is created, for example via co-deposition events that take place in the fog environment that exists in chamber 24.

In chamber 26, a window or buffer layer in the form of cadmium-sulfide (CdS) is applied as a layer 40 extending over the CIGS or CIS layer that was formed in chamber 24. The CdS layer is preferably applied in a non-wet manner by radio-frequency (RF) sputtering. This results in an overall multiple-layer structure such as pictured generally above chamber 26.

After deposition of the Mo, CIGS, and CdS, the strip proceeds through a sequence of operations, 23, 25, 27 designed to first divide, then subsequently, serially connect adjacent ‘divided’ areas. The first operation is to scribe through all deposited layers exposing bare, uncoated substrate. This first scribe functionally divides the elongate strip of deposited layers into plural individual segments and thereby isolates each segment electrically. These segments are held together by the substrate, which remains intact. The scribing technique used is a matter of choice, with the preferred method herein accomplished using a high power density laser.

Directly adjacent to the first scribe operation, a second selective scribe is conducted removing the CdS and CIGS layers but leaving the Mo intact in the as-deposited conditions. This selective scribe forms a via, or channel, that will be later filled in with a conductive oxide.

To prevent the conductive oxide in the top contact layer from ‘filling in’ the first scribe, Mo/CIGS/CdS, and in effect reconnecting adjacent divided Mo regions, the scribe must be filled in with an insulator. Preferably, this is accomplished with a UV curable ink deposited in operation 27 with a commercially adapted ink jet dispense head that is coincident with the high power density laser.

If the optional, electrically insulating, intrinsic-zinc-oxide i-ZnO layer is employed, this is prepared in processing chamber 28 to create a layer arrangement such as that pictured above chamber 28. In this layer arrangement, the i-ZnO layer is shown at 42, overlying the CdS layer.

A top contact layer in the form of a transparent, conductive-oxide overlayer 44, such as ITO or ZnO:Al layer, is formed in processing chamber 30, either directly upon CdS layer 40 if no i-ZnO layer is used, or directly on i-ZnO layer 42 where it is present. The resulting composite layer structure is indicated generally above chamber 30 in FIG. 1.

Where an insulating i-ZnO layer, such as layer 42, is created, the resulting overall layer structure includes what is referred to later herein as a sandwich substructure, indicated generally by arrows 46 in FIG. 1. Substructure 46 includes the i-ZnO layer sandwiched between the CdS layer and the ZnO:Al layer. Thus, where such a sandwich substructure is employed, a contiguous protective intermediary layer (i-ZnO) is provided interposed between the CIGS/CIS layer and the top contact layer 44.

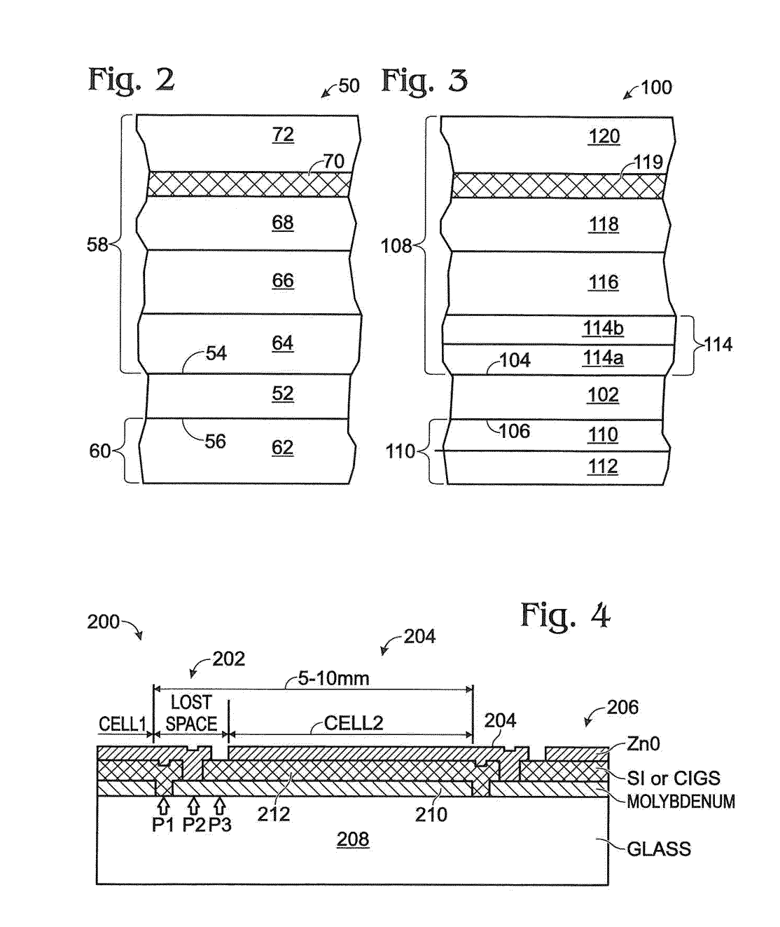

FIGS. 1 and 2 show cross sectional views (not to scale) of a portion of exemplary PV cells in accordance with the present disclosure, including sequential layers deposited onto a first side of a supporting substrate and a protective backside layer structure deposited adjacent a second side of the supporting substrate.

Generally, thin-film PV cells in accordance with the present disclosure may be based on either rigid or flexible substrates. Rigid glass substrates are relatively inexpensive, generally have a coefficient of thermal expansion that is a relatively close match with the CIGS or other absorber layers, and allow for the use of vacuum deposition systems. However, when comparing technology options applicable during the deposition process, rigid substrates suffer from various shortcomings during processing, such as a need for substantial floor space for processing equipment and material storage, expensive and specialized equipment for heating glass uniformly to elevated temperatures at or near the glass annealing temperature, a high potential for substrate fracture with resultant yield loss, and higher heat capacity with resultant higher electricity cost for heating the glass. Furthermore, rigid substrates require increased shipping costs due to the weight and fragile nature of the glass. As a result, the use of glass substrates for the deposition of thin films may not be the best choice for low-cost, large-volume, high-yield, commercial manufacturing of multi-layer functional thin-film materials such as photovoltaics.

Suitable flexible substrate materials include, for example, a high temperature polymer such as polyimide, or a flexible metallic foil (stainless steel foil, titanium foil, aluminum foil or others) or thin metal such as stainless steel, aluminum or titanium, among others. For example, a substrate including a flexible stainless steel may have thickness on the order of 0.025 mm (25 microns), whereas all of the other layers of the cell may have a combined thickness on the order of 0.002 mm (2 microns) or less. In the case of flexible substrates, manufacture of the PV cells may proceed by a roll-to-roll process. Aside from the ability to perform roll-to-roll manufacturing, flexible substrates may have certain advantages over rigid substrates. For example, roll-to-roll processing of thin flexible substrates allows for the use of relatively compact, less expensive vacuum systems, and of some non-specialized equipment that already has been developed for other thin-film industries. Furthermore, flexible substrate materials inherently have lower heat capacity than glass, so that the amount of energy required to elevate the temperature is minimized. Flexible substrates also exhibit a relatively high tolerance to rapid heating and cooling and to large thermal gradients, resulting in a low likelihood of fracture or failure during processing.

Additionally, once active PV materials are deposited onto flexible substrate materials, the resulting unlaminated cells or strings of cells may be shipped to another facility for lamination and/or assembly into flexible or rigid solar modules. This strategic option both reduces the cost of shipping (lightweight flexible substrates vs. glass, for example), and enables the creation of partner-businesses for finishing and marketing PV modules throughout the world. Notwithstanding the potential advantages of using flexible substrates for thin-film PV cells, the present disclosure relates to improving the corrosion resistance of PV cells based upon both flexible and rigid substrates.

A photovoltaic layer structure in accordance with the present disclosure may include sequential layers including at least a contact layer disposed adjacent a first side of the substrate, a p-type semiconductor layer disposed on the first side of the substrate and/or an n-type semiconductor layer disposed on the first side of the substrate. The photovoltaic layer structure may be deposited onto the substrate of a PV cell in individual processing chambers by various processes such as sputtering, evaporation, vacuum deposition, and/or printing. The precise thickness of each layer depends on the exact choice of materials and on the particular application process chosen for forming each layer. Further details regarding these layers, including possible specific layering materials, layer thicknesses, and suitable application processes for each layer are described, for example, in U.S. Pat. No. 7,194,197.

In particular, the semiconductor material copper indium gallium diselenide (CIGS) is stable, has low toxicity, and is truly a thin film, requiring a thickness of less than two microns in a working PV cell. Other semiconductor variants for thin-film PV technology include copper indium diselenide, copper indium disulfide, copper indium aluminum diselenide, and cadmium telluride.

FIG. 4 shows a cross sectional view of a portion of an exemplary monolithically integrated thin film photovoltaic module, generally indicated at 200, and indicates some of the nomenclature commonly used to describe patterning that is typically included in monolithic integration schemes. More specifically, FIG. 4 shows a portion of a first PV cell 202, a second PV cell 204, and a portion of a third cell 206, which have been monolithically integrated on a substrate 208. To form monolithically integrated module 200, a bottom electrode layer 210 is disposed on substrate 208 and then patterned as indicated at P1 to divide the bottom electrode into discrete sections. Patterning P1 (and subsequent patterning described below) results from the removal of portions of material, for example by etching, scribing, lasing, and/or any other suitable method.

An active PV layer 212, typically including a p-n or similar semiconductor junction, is then deposited on top of the bottom electrode layer and within patterning P1. Patterning P2 then provides an interconnect path, or via, between the electrodes. A top electrode layer 214 is then disposed above active PV layer 212 and also within patterning P2. Top electrode 214 is then patterned as indicated at P3, by selectively removing material from the top electrode to divide it into discrete sections. This isolates the cells and completes their fabrication into a series interconnected structure.

The connection between top electrode 214 and bottom electrode 210 within patterning P2 may be compromised by corrosion at the interface of the two electrodes. According to the present teachings, this corrosion may be reduced through the use of a corrosion resistant molybdenum alloy (Mo—X) to construct bottom electrode 210, or at least those portions of the bottom electrode in the vicinity of patterning P2. As described below, the use of Mo—X alloys has been found to resist corrosion more than molybdenum alone or other non-alloy metals that have been used previously for the bottom electrode.

Referring to back to FIG. 2, a thin-film PV cell in accordance with the present disclosure, indicated generally at 50, may include support substrate 52 having a first side 54 and a second side 56. A photovoltaic layer structure 58 may be disposed on first side 54 of the substrate and a protective back side layer structure 60 may be disposed adjacent second side 56 of substrate 52. Protective back side layer structure 60 may include a corrosion resistant layer 62, and may provide corrosion protection for substrate 52 and/or PV cell 50.

The photovoltaic layer structure deposited on the first side of the substrate may include one or more of a back contact layer 64 such as Mo or Cr/Mo; an absorber layer 66 or layers of material such as copper indium diselenide, copper indium disulfide, copper indium aluminum diselenide, or copper indium gallium diselenide (CIGS); a buffer layer 68 or layers such as a layer of cadmium sulfide (CdS); an i-ZnO layer 70 and a top electrode layer 72 such as transparent conducting oxide (TCO). In addition, a conductive current collection grid (not shown), which may be constructed primarily from silver (Ag) or some other conductive metal, is typically applied over the TCO layer.

As described earlier, a PV cell including a protective back side layer deposited adjacent the second side of the substrate may include a corrosion resistant material and may provide corrosion protection for the PV cell. In accordance the present disclosure, PV cell 50 includes protective back side layer structure 60. Protective back side layer structure 60 may include a layer 62 including a corrosion resistant material. Layer 62 may be disposed directly adjacent second side 56 of substrate 52. Alternatively, there may be an intervening layer, not shown, between layer 62 and the second side of the substrate.

Layer 62 may include a corrosion resistant material, such as a Mo—X alloy. Various Mo—X alloys, or a combination of several different Mo—X alloys, may be used to resist corrosion. For example, binary, ternary, or multicomponent films may be used as Molybdenum alloy Mo—X. The additional element (or elements) X may be selected from groups IVb, Vb, IIIA and/or IVA of the periodic system of elements (PSE), and Ti, Zr, Hf, V, Nb, Ta, Al, and Si may be particularly suitable. In some embodiments, it may be desirable that the alloy partner forms a solid solution with the Molybdenum matrix, for reasons of production process integration and feasibility. Further, in some embodiments it may be preferable that the free reaction enthalpy for the formation of oxide species of the alloy partner or partners will be higher than the free reaction enthalpy of Molybdenum itself, so that the alloy partner will preferentially corrode.

The alloy may be chosen to be low in overall resistivity, so that the increase of electrical resistivity due to alloying may be kept at a minimum by choosing a low amount of the alloying element. For example, the content of the alloyed element (i.e. the atomic concentration) may be chosen to be lower than 25%, or even lower than 10%. The Mo—X alloy may be formed by any suitable means of thin film deposition processes, such as sputtering, evaporation, chemical vapor deposition, pulsed laser deposition, chemical solution deposition, spray deposition, thin film reaction processes, implanting an alloy partner, or other combined methods for thin film fabrication.

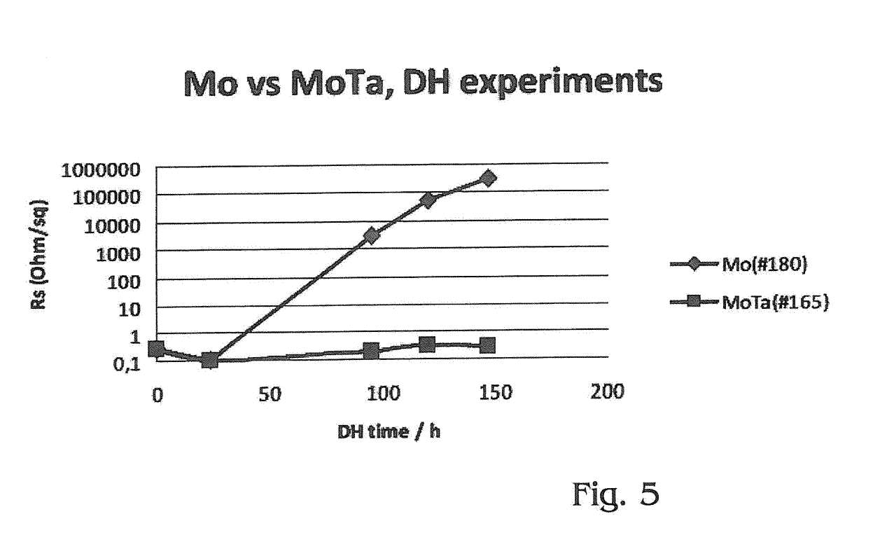

The back side of the substrate may be relatively easily corroded when exposed to humidity if coated with a single back side layer including only pure Mo. A protective back side layer deposited on the second side of the substrate in accordance with the present disclosure may offer improved corrosion resistance over a back side layer of Mo alone and, therefore, better protection for the second side of the substrate. FIG. 5 is a graph comparing the electrical resistance of a thin film of Mo and a thin film of molybdenum-tantalum (MoTa) as a function of hours of exposure to damp heat, according to aspects of the present disclosure. The electrical resistance was measured by means of a 4-point probe setup. As FIG. 5 indicates, the Mo thin film sample increases dramatically in sheet resistance after only approximately 100 h of damp heat (DH) testing, whereas the sputtered MoTa film shows a very high corrosion resistance, and no significant increase in sheet resistance was observed. The atomic Ta content for the MoTa sample represented in FIG. 5 was 5% (Mo95Ta5).

As another indication of the corrosion resistance of Mo—X alloys, the chart below compares the optical appearance of sputtered samples of Mo and MoTa after various times of exposure to damp heat (DH), according to aspects of the present disclosure.

| DH Time (hours) | Mo | MoTa |
|---|---|---|
| 0 | Metallic, shiny | Metallic, shiny |
| 24 | Metallic, few spots | Metallic, shiny |
| 95 | Corroded | Metallic, shiny, few spots, |
| | | spots mainly at edge |
| 120 | Heavily corroded | Metallic, shiny, few spots, |
| | | spots mainly at edge |
| 147 | Heavily corroded | Metallic, shiny, few spots, |
| | | spots mainly at edge |

As can be seen by a comparison of FIG. 5 with the chart, the increase in electrical resistance corresponds closely to the discoloration and visible corrosion of the samples. It is believed that the surface of the Mo film is transformed into highly insulating Mo03, whereas the MoTa alloy successfully prevents the formation of a corroded insulating MoOx layer. This allows the solar cell contacts to be exposed to a moisture containing ambient for a long time without suffering a degradation of the interconnect resistance.

Additionally and/or alternatively, referring back to FIG. 3, a thin-film PV cell in accordance with the present disclosure, indicated generally at 100, may include a support substrate 102 having a first side 104 and a second side 106. A photovoltaic layer structure 108 disposed on first side 104 of the substrate and a protective back side layer structure 110 may be disposed adjacent second side 106 of substrate 102. Protective layer structure 110 may include a first layer 111 adjacent to the second side 106 and a second layer 112 adjacent to the first layer 110. One or both of first layer and second layer may be corrosion resistant. Furthermore, first layer 110 may act to relieve stress on substrate 102 by keeping it relatively smooth and flat, and may promote the adhesion of the second layer. In some embodiments, first layer 110 may include chromium (Cr) and second layer 112 may include Mo.

Photovoltaic layer structure 108 deposited on first side 104 of the substrate may include one or more of a back contact layer 114 such as Mo or Cr/Mo (114a/114b); an absorber layer 116 or layers of material such as copper indium diselenide, copper indium disulfide, copper indium aluminum diselenide, or copper indium gallium diselenide (CIGS); a buffer layer 218 or layers such as a layer of cadmium sulfide (CdS); a i-ZnO layer 219 and a top electrode layer 220 such as transparent conducting oxide (TCO). In addition, a conductive current collection grid (not shown), which may be constructed primarily from silver (Ag) or some other conductive metal, is typically applied over the TCO layer.

A protective layer structure having two layers may have a thickness ranging from approximately 70 nm-1300 nm, where a first layer, such as a Cr layer, may range in thickness from approximately 20 nm-300 nm and a second layer, such as a Mo layer, may range in thickness from approximately 50 nm-1000 nm.

Back contact layer generally may have a thickness ranging from approximately 220 nm-1300 nm, where a chromium layer may range in thickness from approximately 20 nm-300 nm and a molybdenum layer ranges in thickness from approximately 200 nm-1000 nm. Sputtering powers may range from 5.5 kW to 8.5 kW, and/or operating pressures may range from 4 mT to 8 mT. For example, a second layer including Mo may be sputtered at 7.5 kW and at an operating pressure of 6 mTorr.

Although the precise thickness of each layer of a thin-film PV cell depends on the exact choice of materials and on the particular application process chosen for forming each layer, exemplary materials, thicknesses and methods of application of each layer described above for PV cell 100 are as follows, proceeding in typical order of application of each layer onto substrate 102:

| | Exemplary | Exemplary | Exemplary Method |
|---|---|---|---|
| Layer Description | Material | Thickness | of Application |
| Protective Back side | Cr/Mo | 130 nm | Sputtering |
| layer structure | | | |
| Substrate | Stainless steel | 25 μm | N/A (stock material) |
| Back contact bi-layer | Cr/Mo | 320 nm | Sputtering |
| Absorber | ClGS | 1700 nm | Evaporation |
| Buffer | CdS | 80 nm | Chemical deposition |
| Front electrode | TCO | 250 nm | Sputtering |
| Collection grid | Ag | 40 μm | Printing |

Accordingly, a Cr/Mo bi-layer applied as a protective back layer coating may provide greater corrosion resistance to the back side of the substrate than a pure Mo back layer. Corrosion testing of substrate panels coated with Cr/Mo back side protective bi-layers of various thicknesses supports this inference.

The various structural members disclosed herein may be constructed from any suitable material, or combination of materials, such as metal, plastic, nylon, rubber, or any other materials with sufficient structural strength to withstand the loads incurred during use. Materials may be selected based on their durability, flexibility, weight, and/or aesthetic qualities.

It is believed that the following claims particularly point out certain combinations and subcombinations that are directed to one of the disclosed inventions and are novel and non-obvious. Inventions embodied in other combinations and subcombinations of features, functions, elements and/or properties may be claimed through amendment of the present claims or presentation of new claims in this or a related application. Such amended or new claims, whether they are directed to a different invention or directed to the same invention, whether different, broader, narrower or equal in scope to the original claims, are also regarded as included within the subject matter of the inventions of the present disclosure.

We claim:

1. A thin film photovoltaic cell, comprising:
a support substrate having a first side and a second side,
a contact layer disposed on the first side of the substrate,
an absorber layer disposed on the first side of the substrate,
a buffer layer disposed on the first side of the substrate, and
a protective back side layer on the second side of the substrate, wherein the protective back side layer structure includes a corrosion resistant material.

2. The thin film photovoltaic cell of claim 1, wherein the back side layer includes at least a first layer and a second layer.

3. The thin film photovoltaic cell of claim 2, wherein the first layer includes chromium.

4. The thin film photovoltaic cell of claim 3, wherein the first layer including chromium is disposed directly adjacent the second side of the substrate.

5. The thin film photovoltaic cell of claim 2, wherein the second layer comprises the same material included in the contact layer on the first side of the substrate.

6. The thin film photovoltaic cell of claim 1, wherein the substrate has molybdenum deposited on the first side and the second side of the substrate.

7. The thin film photovoltaic cell of claim 1, wherein the contact layer includes a layer containing chromium disposed adjacent the first side of the substrate and a layer containing molybdenum disposed adjacent the chromium contact layer.

8. The thin film photovoltaic cell of claim 1, wherein the back side layer has a thickness of from 150 nm to 275 nm.

9. The thin film photovoltaic cell of claim 1, wherein the back side layer includes a molybdenum alloy.

10. The thin film photovoltaic cell of claim 9, wherein the molybdenum alloy includes an alloy partner selected from the group consisting of Ti, Zr, Hf, V, Nb, Ta, Al, and Si.

11. The thin film photovoltaic cell of claim 9, wherein the atomic concentration of the alloy partner is less than 25%.

12. The thin film photovoltaic cell of claim 11, wherein the atomic concentration of the alloy partner is less than 10%.

13. A method of producing a flexible, thin-film photovoltaic (PV) structure comprising:
providing a support substrate having a first side and a second side,
applying a photovoltaic layer on the first side of the substrate, and
applying a protective back side layer on the second side of the substrate, wherein the protective back side layer includes a corrosion resistant material.

14. The method of claim 13, wherein applying the protective back side layer structure includes applying at least two layers, one of the at least two layers includes molybdenum (Mo).

15. The method of claim 14, wherein one of the at least two layers includes chromium (Cr), the step of applying a protective back side layer includes forming the layer including chromium directly adjacent the substrate, and forming a layer including molybdenum (Mo) directly adjacent the layer including chromium.

16. The method of claim 14, wherein applying a protective back side layer includes applying a first layer and a second layer having a thickness ratio of 1:2.

17. The method of claim 13, wherein applying the protective back side layer includes applying a molybdenum-alloy layer.

18. The method of claim 17, wherein the molybdenum alloy includes an alloy partner selected from the group consisting of Ti, Zr, Hf, V, Nb, Ta, Al, and Si.

19. The method of claim 17, wherein the molybdenum alloy includes at least one alloy partner selected from groups IVb, Vb, IIIA, and IVA from the periodic table.
